(19) United States
(12) Patent Application Publication
(10) Pub. No.: US 2025/0393267 A1
(43) Pub. Date: Dec. 25, 2025

(54) SEMICONDUCTOR STRUCTURE AND METHOD OF FORMING THE SAME

(71) Applicant: NANYA TECHNOLOGY CORPORATION, New Taipei City (TW)

(72) Inventor: Tseng-Fu LU, New Taipei City (TW)

(21) Appl. No.: 18/752,764

(22) Filed: Jun. 24, 2024

(51) Int. Cl. H01L 29/06; H01L 21/762; H01L 21/3105; H10B 12/00

(52) U.S. Cl. CPC H10D 62/124; H01L 21/31058; H01L 21/76224; H10B 12/488

(57) ABSTRACT

The invention provides a semiconductor structure. The semiconductor structure includes a substrate. The substrate includes active areas extending along a first direction and an isolation structure defining the active areas. The semiconductor structure further includes word line structures extending along a second direction in the substrate across a portion of the active areas, and separating each of the active areas into a center portion and end portions, wherein each of the end portions has at least two curvatures.

### BACKGROUND

### FIELD OF INVENTION

The present invention relates to memory array and a method of forming active areas in the memory array. More particularly, the present invention relates to a dynamic random access memory (DRAM) array and a method for forming active areas of the DRAM array.

### DESCRIPTION OF RELATED ART

In recent decades, demand to storage capability and lower cost has increased as electronic products continue to improve. In order to increase the storage capability of a memory device (e.g., a DRAM device), more memory cells are arranged in the memory device, and each memory cell in the memory device becomes smaller in size. The memory cells are respectively fabricated on an active area, which is a portion of a semiconductor substrate. Scaling of the active areas is an alternative for reducing size of each memory cell.

Each DRAM cell may include a storage capacitor disposed over an active area and connected to the active area through a capacitor contact. Reduction of the active area may result in shrinkage of a contact area between the capacitor contact and the active area, and may raise a contact resistance of the capacitor contact. Particularly, such shrinkage of contact area may decrease the write/read performance of DRAM. Therefore, a method for improving the contact resistance without any side effect is important in the art.

### SUMMARY

The invention provides a semiconductor structure. The semiconductor structure includes a substrate. The substrate includes active areas extending along a first direction and an isolation structure defining the active areas. The semiconductor structure further includes word line structures extending along a second direction in the substrate across a portion of the active areas, and separating each of the active areas into a center portion and end portions, wherein each of the end portions has at least two curvatures.

The invention provides a method of forming a semiconductor structure. The method includes forming linear active areas in a substrate, wherein the linear active areas are parallel to each other and extend along a first direction. The method further includes patterning the linear active areas to form active areas, forming an isolation structure on the substrate to isolate the active areas from each other, and forming word line structures in the substrate and extending along a second direction across a portion of the active areas, and separating each of the active areas into a center portion and end portions, wherein each of the end portions has at least two curvature.

These and other features, aspects, and advantages of the present invention will become better understood with reference to the following description and appended claims.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1, 3, 4, 6, 12 are cross-sectional views of various formation stages of a method of forming a semiconductor structure according to some embodiments of the present disclosure.

FIGS. 2, 5, 7-9, 10A-10B, 11, 13 are top views of a method of forming a semiconductor structure at different stages according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

It will be understood that, although the terms “first”, “second”, “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Furthermore, relative terms, such as “lower” or “bottom” and “upper” or “top”, may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper”, depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

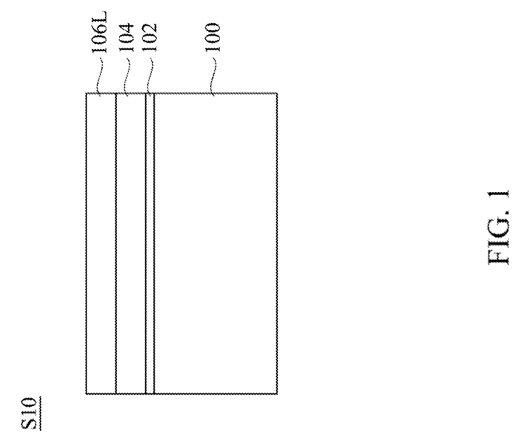

FIGS. 1, 3, 4, 6, 12 are cross-sectional views of various formation stages of a method of forming a semiconductor structure 10 according to some embodiments of the present disclosure.

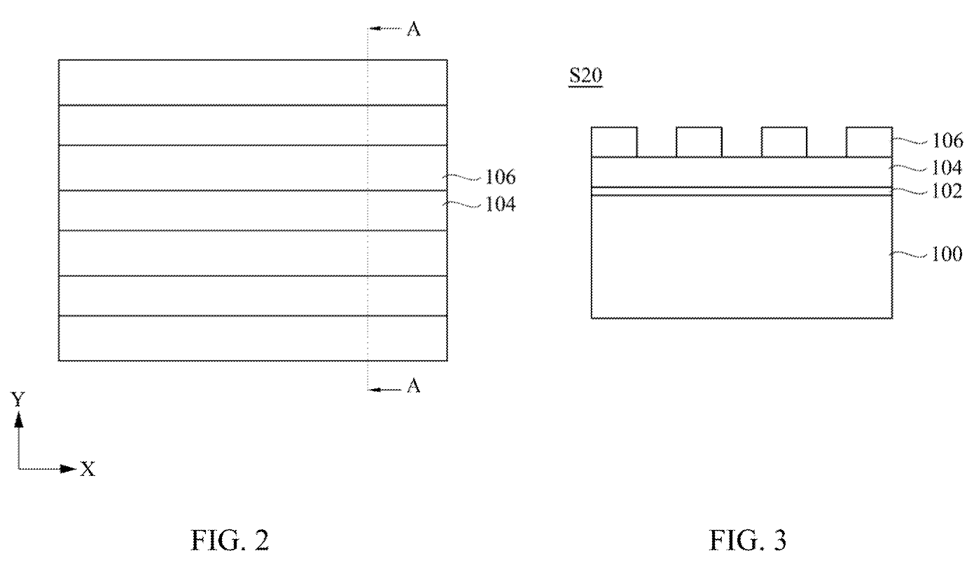

FIGS. 2, 5, 7-9, 10A-10B, 11, 13 are top views of various formation stages of a method of forming a semiconductor structure 10 according to some embodiments of the present disclosure.

Referring to FIG. 1, the method begins from step S10. A substrate 100 is provided. An oxide layer 102, a mask layer 104 and a photoresist layer 106L are sequentially stacked over the substrate 100. In some embodiments, the mask layer 104 may be served as a hard mask to protect active regions of the substrate 100 during an etching operation without being consumed in subsequent processing steps. In some embodiments, the mask layer 104 includes silicon nitride layer.

Referring to FIG. 2 and FIG. 3. FIG. 3 is a cross-section view of the semiconductor structure across the plane A-A shown in FIG. 2. The method goes to S20. The photoresist layer 106L is patterned to form a plurality of first photoresists 106. The plurality of the first photoresists 106 extend along an x axis. After the formation of the first photoresists 106, portions of the mask layer 104 are exposed.

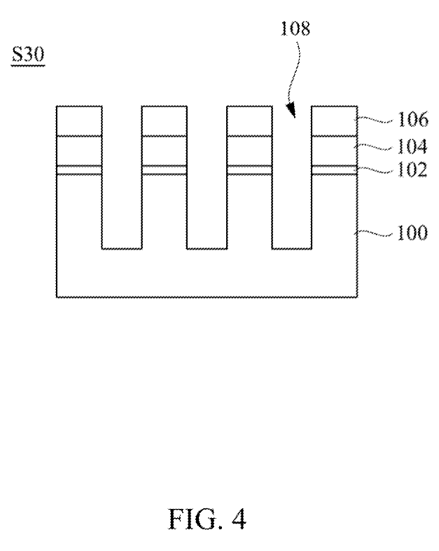

Referring to FIG. 4, the method goes to S30. The mask layer 104, oxide layer 102 are patterned by an etching process using the first photoresists 106 as a mask. A plurality of trenches 108 are sequentially formed in the substrate 100 based on positions where the pattern of the first photoresists 106 align with. The plurality of the trenches 108 extend downward from a top surface of the substrate 100. The plurality of the trenches 108 are used to accumulate a following isolation structure. The formation of the plurality of the trenches 108 may be used any suitable operation, such as an anisotropic dry etch process.

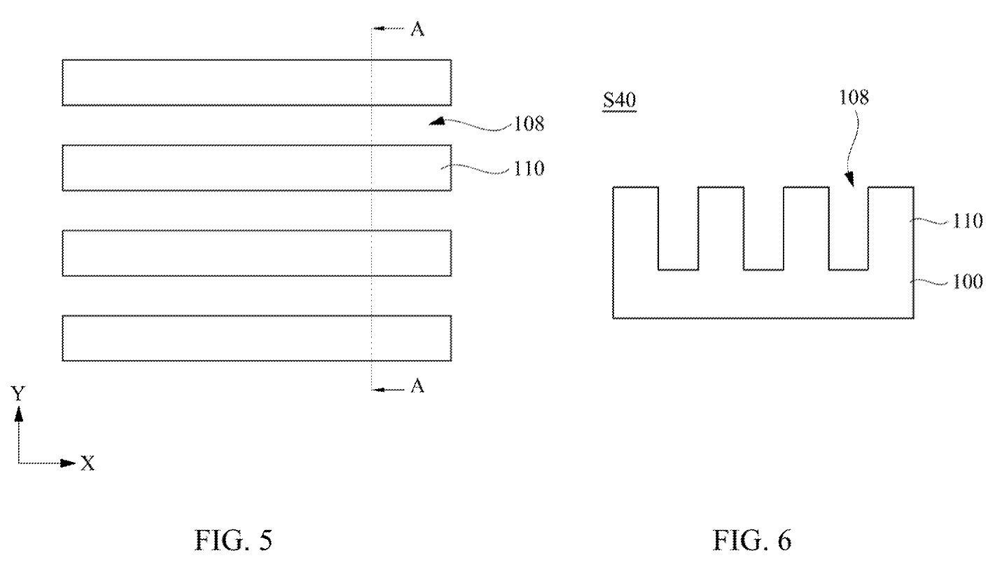

Referring to FIG. 5 and FIG. 6. FIG. 6 is a cross-section view of the semiconductor structure across the plane A-A shown in FIG. 5. The method goes to S40. The first photoresist 106, oxide layer 102 and mask layer 104 (as shown in FIG. 4) are removed and a plurality of linear active areas 110 are defined in the substrate 100. The plurality of the trenches 108 are located between the adjacent linear active areas 110. Both of the trenches 108 and the linear active areas 110 extend along the x axis.

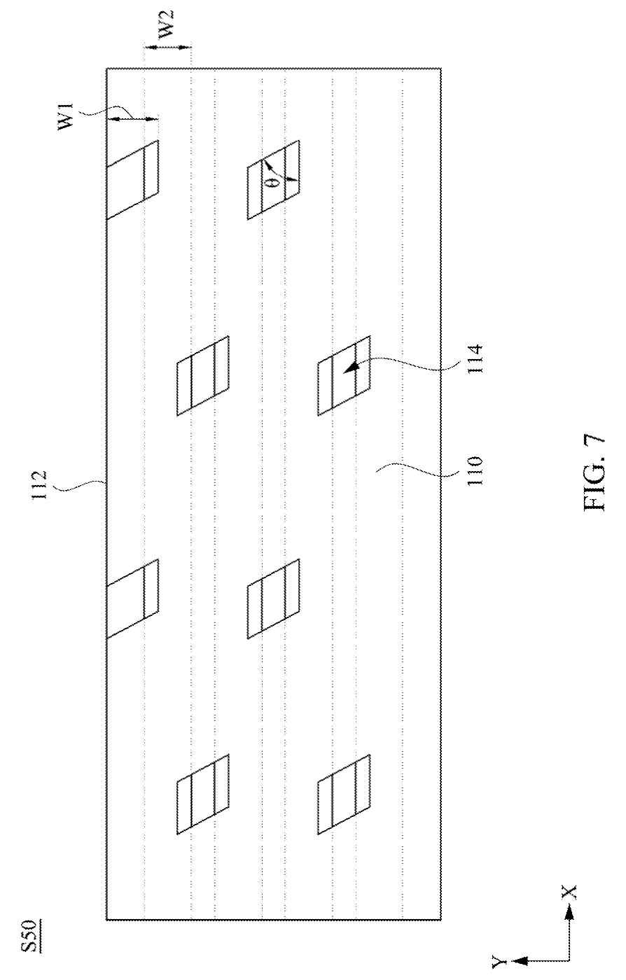

Referring to FIG. 7, the method goes to S50. A second photoresist 112 is formed on the substrate 100. The formation of the second photoresist 112 may be formed by deposition of a photoresist material, followed by patterning the photoresist material.

The second photoresist 112 have a plurality of openings 114. The openings 114 expose a portion of the linear active areas 110. In some embodiments, a center of each of the openings 114 may be formed between the adjacent linear active areas 110. In some embodiments, a center of the each of the openings 114 may be formed over the linear active areas 110. Each of the openings 114 may be alternatively arranged.

The shape of the openings 114 may be parallelogram shape. Opposite sides of the openings 114 may extend along the x axis, and the other opposite sides of the openings 114 may have an angle θ with the x axis. The angle θ may be defined by the other opposite sides of the openings 114 and the x axis. The angle may be various due to the requirements of the process. Each of the openings 114 may have a width W1, which is the maximum distant of the openings 114 in a y direction. Each of the linear active areas 110 may have a width W2 in the y direction. In some embodiments, W1 may be larger, approximately equal to, or less than a width W2 of each of the linear active areas 110, based on the necessary of the process.

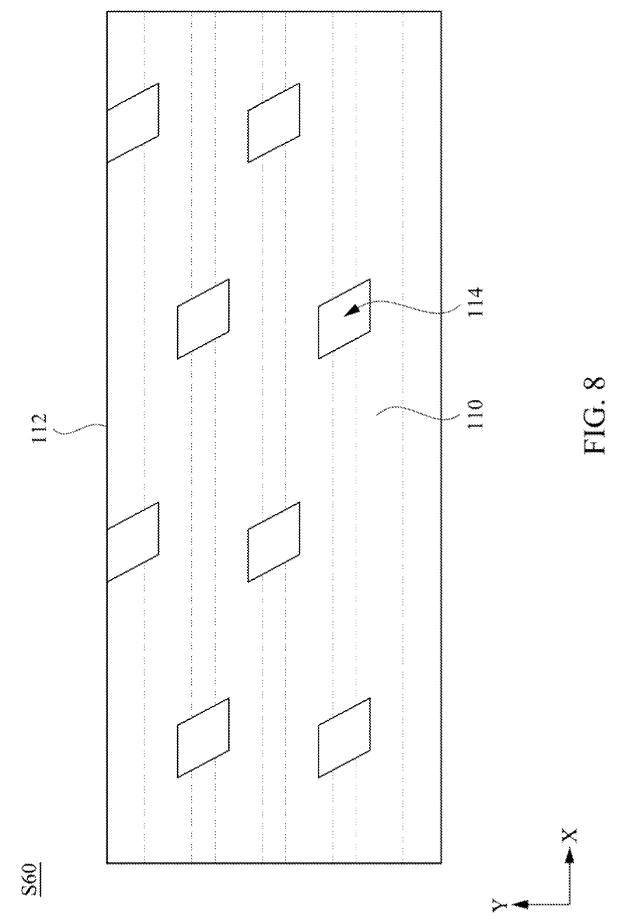

Referring to FIG. 8, the method goes to S60. An etching operation is performed to remove the portion of the linear active areas 110 exposed by the openings 114 to form a plurality of active areas 116.

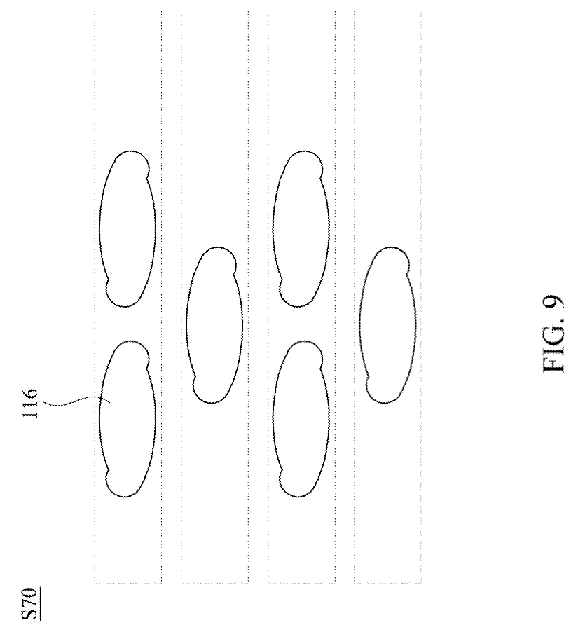

Referring to FIG. 9, the method goes to S70. Due to the resolution and the limitation of the process operation, a pattern of the openings 114 of the second photoresist 112 may not be transferred completely from the second photoresist 112 to the linear active areas 110. A plurality of the active areas 116 are formed in the substrate. The plurality of the linear active areas 110 (shown in FIG. 7) are cut into the plurality of the active areas 116 with a specific shape by the openings 114 with parallelogram shape. The plurality of active areas 116 spaced apart from each other and arranged alternatively.

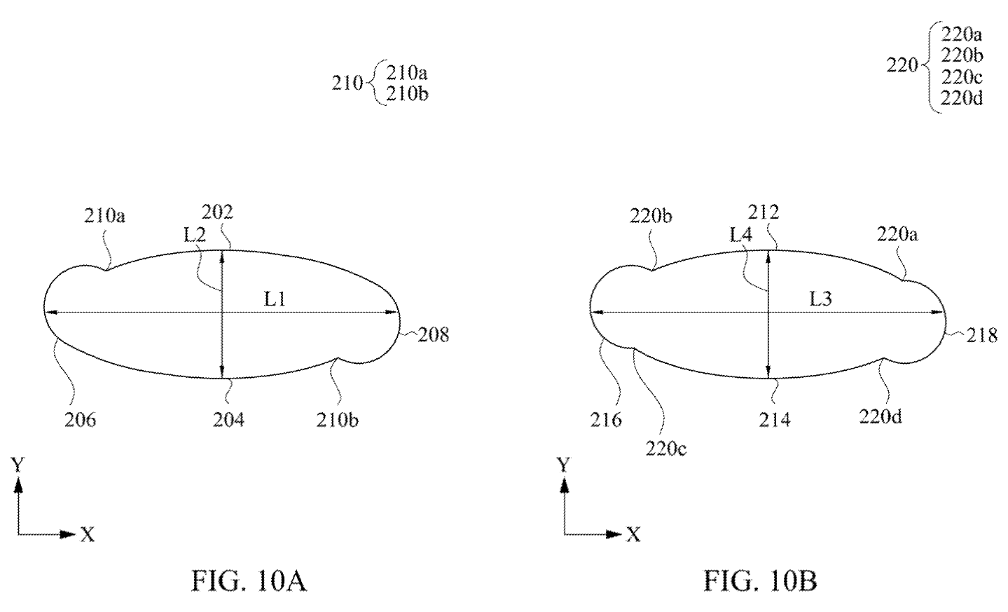

Referring to FIG. 10A, FIG. 10A is a diagram of an embodiment of the active area 116 of the semiconductor structure of the present disclosure. Based on the openings 114 with the parallelogram shape, each of the plurality of the active areas 116 may include a long axis L1 and a short axis L2. The long axis L1 extends in the x direction and the short axis L2 extends in the y direction. The plurality of the active areas 116 may be an ellipse-like shape along the long axis L1 but both ends are curves with larger curvature. The plurality of the active areas 116 with the ellipse-like shape includes perimeters 202 and 204 along the long axis and curves 206 and 208 at both ends. The perimeters 202 and 204 connect to the curves 206 and 208. The perimeters 202 and 204 along the long axis may have curvature C1. The curves 206 and 208 at both ends may have curvature C2. The curvature is one of an index of bending degree of curves, which may imply a curve deviating from being a straight line. Small circles bend more sharply, resulting a larger curvature. On the contrary, smoother curve may have a smaller curvature. The curvature of a straight line is zero. The curves 206 and 208 may be approximately equal to a half circle. Hence, the curvature C1 of the perimeters 202 and 204 along the long axis is smaller than the curvature C2 of the curves 206 and 208 at both ends.

The perimeters 202 and 204 along the long axis may have radius of curvature R1. The curves 206 and 208 at both ends may have radius of curvature R2. The radius of curvature is related to the radius of the circular arc which best approximates the curve at that point. The curve bends sharply, resulting smaller radius of the curvature. The smoother curve may have a larger radius of the curvature. As the result, the radius of curvature R1 of the perimeters 202 and 204 along the long axis may be larger than the radius of curvature R2 of the curves 206 and 208 at both ends.

It turns out at least two inflection point 210 are located between the perimeters 202 and 204 along the long axis L1 of the active areas 116 and the curves 206 and 208 at both ends of the active areas 116 due to the variation of the curvature. Each of the inflection points 210 may be disposed near one ends of the active areas 116. In some embodiment, one inflection point 210a is present between one side of the curve 206 and the perimeter 202, and between the other side of the curve 206 and the perimeter 204 may be a smooth and continuous curve. Another inflection point 210b is present between one side of the curve 208 and the perimeter 204, and between the other side of the curve 208 and the perimeter 202 may be a smooth and continuous curve. Therefore, the plurality of the active areas 116 may have two inflection points 210 (e.g., each of the inflection points 210a and 210b may be at each end of the active areas 116).

The curves 206 and 208 at both ends may have variant curvature due to the pattern of the openings 114. In some embodiments, the openings 114 may be parallelogram shape with angleθ(shown in FIG. 7). In some embodiments, the curvature C2 of the curves 206 and 208 at both ends depends on the angleθ. The curvature C2 of the curve 206 and 208 at both ends may get larger as the angle becomes smaller. The curvature C2 of the curves 206 and 208 at both ends may get smaller as the angle gets larger. In some embodiments, the radius of curvature R2 of the curves 206 and 208 at both ends depends on the angle θ as well. The radius of curvature R2 of the curves 206 and 208 at both ends may get smaller as the angle becomes smaller. The curvature C2 of the curve 206 and 208 at both ends may get larger as the angle gets larger. The curves 206 and 208 at both ends may extend along a diagonal direction of the plurality of the active areas 116 due to the openings 114 with the parallelogram shape.

Referring to FIG. 10B, FIG. 10B is a diagram of another embodiment of the active area 116 of the semiconductor structure of the present disclosure. Each of the plurality of the active areas 116 may include a long axis L3 and a short axis L4. The long axis L3 extends in the x direction and the short axis L4 extends in the y direction. The plurality of the active areas 116 may be an ellipse-like shape along the long axis L3 but both ends are curves with larger curvature. The plurality of the active areas 116 with the ellipse-like shape includes perimeters 212 and 214 along the long axis and curves 216 and 218 at both ends. The perimeters 212 and 214 along the long axis may have curvature C3. The curves 216 and 218 at both ends have curvature C4. The curves 216 and 218 may be approximately equal to a half circle. The curvature C3 of the perimeters 212 and 214 along the long axis is smaller than the curvature C4 of the curves 216 and 218 at both ends.

The perimeters 212 and 214 along the long axis may have radius of curvature R3. The curves 206 and 208 at both ends may have radius of curvature R4. The radius of curvature R3 of the perimeters 212 and 214 along the long axis may be larger than the radius of curvature R4 of the curves 216 and 218 at both ends.

There are four inflection points 220 located between the perimeters 212 and 214 along the long axis of the active areas 116 and the curves 216 and 218 at both ends of the active areas 116 due to the variation of the curvature. Each of the inflection points 220 may be disposed near one ends as well. In some embodiment, inflection point 220a is present between one side of the curve 218 and one side of the perimeter 212, and inflection point 220d is present between the other side of the curve 218 and one side of the perimeter 214. Inflection point 220b is present between one side of the curve 216 and the other side of the perimeter 212, and inflection point 220c is present between the other side of the curve 216 and the other side of the perimeter 214. Therefore, the plurality of the active areas 116 may have two inflection points 220a and 220d (or 220b and 220c) at one end of the active areas 116.

The curves 216 and 218 at both ends may have variant curvature due to the pattern of the openings 114. In some embodiments, the openings 114 may be parallelogram shape with angle θ. In some embodiments, the curvature C4 of the curves 216 and 218 at both ends depends on the angle θ. The curvature C4 of the curves 216 and 218 at both ends may get larger as the angle becomes smaller. The curvature C4 of the curves 216 and 218 at both ends may get smaller as the angle gets larger. In some embodiments, the radius of curvature R4 of the curves 216 and 218 at both ends depends on the angle θ. The radius of curvature R4 of the curves 216 and 218 at both ends may get smaller as the angle becomes smaller. The radius of curvature R4 of the curves 216 and 218 at both ends may get larger as the angle gets larger. The curves 216 and 218 at both ends may extend along a diagonal direction of the plurality of the active areas due to the openings 114 with parallelogram shape.

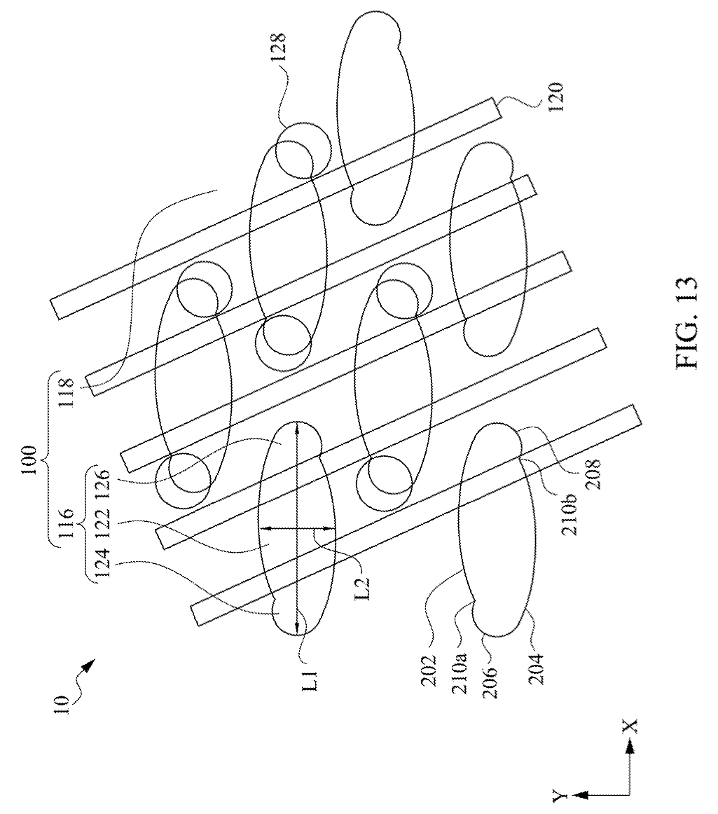

The active areas 116 with such a specific shape may enlarge only the area of both ends with reference to FIG. 10A and 10B. The enlarged area of both ends may extend landing area which is surface area between the active areas 116 and capacitor contacts (shown in FIG. 13). The capacitor contacts may electrically and/or physically connects the active areas 116 to the capacitors. The enlarged area of both ends may have benefits of decreasing the contact resistance. In some embodiments, for the demand of decreasing the contact resistance, the active areas 116 may be enlarged overall. As the results, the space of the active areas 116 may be reduced, and the active areas 116 may be closer to each other, easily causing the cell-cell short.

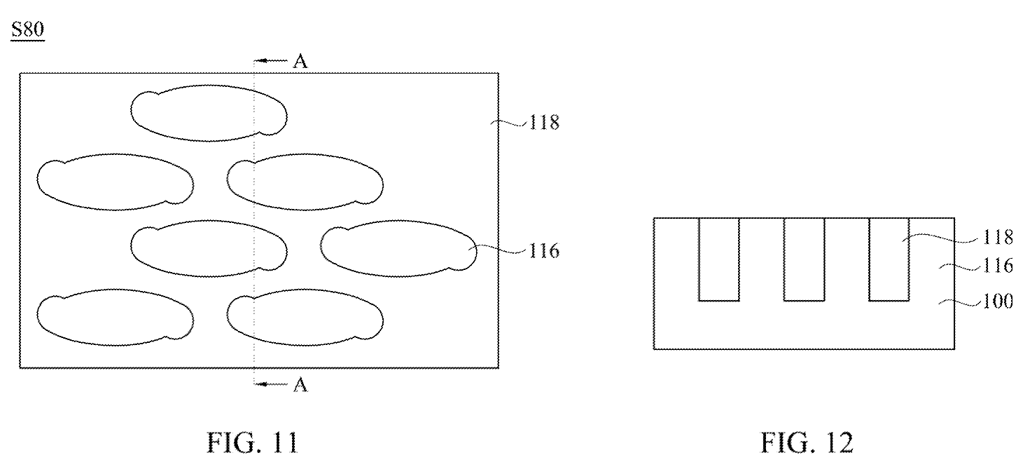

Referring to FIG. 11 and FIG. 12. FIG. 12 is a cross-section view of the semiconductor structure across the plane A-A shown in FIG. 11. The method goes to S80. A dielectric material is deposited in the space between the active areas 116 followed by a planarization process to form the isolation structure 118 in the substrate 100. The plurality of the active areas 116 are surrounded by the isolation structure 118, and the plurality of the active areas 116 are spaced apart by the isolation structure 118. In some embodiments, the isolation structure 118 may be regarded as shallow trench isolation (STI). In some embodiments, the deposition may include any suitable operations, such as chemical vapor deposition (CVD). The removal may include any suitable operations, such as a chemical mechanical planarization (CMP), anisotropic etch, combination thereof, or the like. After the planarization process, a top surface of the isolation structure 118 is coplanar with a top surface of the active areas 116.

Referring to FIG. 13, a plurality of word line structures 120 are formed in the substrate 100 across a portion of the plurality of the active areas 116. The plurality of the word line structures 120 may extend in a diagonal axis with respect to the x axis. Each of the plurality of the active areas 116 is passed through by adjacent word line structures 120 and separated into three portions called center portion 122 and end portions 124 and 126. The center portion 122 is disposed between the end portions 124 and 126 and connects to both end portions 124 and 126.

The center portion 122 of the active areas 116 includes a portion of the perimeters 202 and 204 along the long axis L1. In other words, the curvature at the center portion 122 is approximately the same. The end portions 124 of the active areas 116 include the curves 206 and a portion of the perimeters 202 and 204 along the long axis L1. In other words, the curvatures at the end portions 124 may be different. The end portions 126 of the active areas 116 include the curves 208 and a portion of the perimeters 202 and 204 along the long axis L1. In other words, the curvatures at the end portions 126 may be different. Each of the end portions 124 and 126 may have two different curvatures. Further, an average curvature of the end portions 124 and 126 is larger than an average curvature of the center portion 122. The curves 206 and 208 are present at the end portions, so that the end portions 124 and 126 may extend along the diagonal direction of the plurality of the active areas.

Such a shape of the active areas 116 may provide the enlarged area of the end portions 124 and 126. The capacitor contacts 128 may stand on the landing areas of the active areas 116 at end portions 124 and 126, and electrically and/or physically connect the active areas 116 to the capacitor (not shown). The enlarged area of the end portions 124 and 126 may increase the contact area between the active areas 116 and the capacitor contacts 128, resulting in decreasing the contact resistance.

The semiconductor structure 10 formed by the method of forming the semiconductor structure is provided in FIG. 13. The semiconductor structure 10 includes the substrate 100. The substrate 100 includes the plurality of the active areas 116 and the isolation structure defining the plurality of the active areas 116. The plurality of the word line structures 120 are formed in the substrate 100 and across the portion of the plurality of the active areas 116. Each of the active areas 116 may be through by adjacent word line structures 120 and separated into three portions. Three portions of the active areas 116 include the center portion 122 and end portions 124 and 126. The center portion 122 is disposed between the end portions124 and 126 and connects to the end portions124 and 126. Each of the active areas 116 may include a long axis L1 and a shore axis L2. The active areas 116 may be in an ellipse-like shape, including the perimeters 202 and 204 along the long axis L1 of the active areas 116 and the curves 206 and 208 at both ends of the active areas 116. The perimeter 202 and 204 may have the curvature C1 and the curves 206 and 208 may have the curvature C2. The curvature C1 of the perimeter 202 and 204 may be less than the curvature C2 of the curves 206 and 208. The perimeter 202 and 204 may have the radius of curvature R1 and the curves 206 and 208 may have the radius of curvature R2. The radius of curvature R1 of the perimeter 202 and 204 may be larger than the radius of curvature R2 of the curves 206 and 208.There is at least two inflection points between the perimeter 202 and 204 and the curves 206 and 208.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor structure, comprising:
a substrate, comprising:
a plurality of active areas extending along a first direction; and
an isolation structure defining the plurality of the active areas; and
a plurality of word line structures extending along a second direction in the substrate across a portion of the plurality of the active areas, and separating each of the plurality of the active areas into a center portion and end portions,
wherein each of the end portions has at least two curvatures.

2. The semiconductor structure of claim 1, wherein each of the end portions has at least one inflection point.

3. The semiconductor structure of claim 1, wherein each of the end portions has at least two inflection points.

4. The semiconductor structure of claim 1, wherein each of the end portions extends along a diagonal direction of the plurality of the active areas.

5. The semiconductor structure of claim 1, wherein the plurality of the active areas are alternatively arranged.

6. The semiconductor structure of claim 1, wherein the plurality of the active areas are ellipse-like shape.

7. The semiconductor structure of claim 1, wherein an average curvature of the end portions is larger than an average curvature of the center portion.

8. A method of forming a semiconductor structure, comprising:
forming a plurality of linear active areas in a substrate, wherein the plurality of the linear active areas are parallel to each other and extend along a first direction;
patterning the plurality of the linear active areas to form a plurality of active areas;
forming an isolation structure in the substrate to isolate the plurality of the active areas from each other; and
forming a plurality of word line structures in the substrate and extending along a second direction across a portion of the plurality of the active areas, and separating each of the plurality of the active areas into a center portion and end portions,
wherein each of the end portions has at least two curvature.

9. The method of claim 8, wherein the patterning the plurality of the linear active areas to form a plurality of active areas comprising:
providing a photoresist layer on the substrate;
patterning the photoresist layer to form openings;
removing portions of the plurality of the linear active areas; and
removing the photoresist layer.

10. The method of claim 9, wherein the openings have parallelogram shape.

11. The method of claim 9, wherein the openings are alternatively arranged.

12. The method of claim 9, wherein centers of the openings are located between adjacent plurality of the linear active areas.

13. The method of claim 9, wherein the openings have a width larger than a width of the plurality of the linear active areas.

14. The method of claim 9, wherein the openings have a width approximately equal to a width of the plurality of the linear active areas.

15. The method of claim 8, wherein each of the end portions extends along a diagonal direction of the plurality of the active areas.

16. The method of claim 8, wherein an average curvature of the end portions is larger than an average curvature of the center portion.
